(19) United States
(12) Patent Application Publication
(10) Pub. No.: US 2021/0332931 A1
(43) Pub. Date: Oct. 28, 2021

(54) PIPING SYSTEM AND PROCESSING APPARATUS

(71) Applicant: Tokyo Electron Limited, Tokyo (JP)

(72) Inventors: Kazuki HOSHI, Miyagi (JP); Koji YAMAGISHI, Miyagi (JP)

(21) Appl. No.: 17/232,674

(22) Filed: Apr. 16, 2021

(30) Foreign Application Priority Data
Apr. 24, 2020 (JP) 2020-077574

(51) Int. Cl. F16L 59/02; F16L 59/12; F28F 9/02

(52) U.S. Cl. CPC F16L 59/02; H01L 21/3065; F28F 9/02; F16L 59/121

(57) ABSTRACT

A piping system includes: pipes, each of which is covered with a heat-insulating member and through which a cooling medium flows; and a heat transfer member arranged between two heat-insulating members of two of the pipes adjacent to each other. The heat transfer member includes: a contact portion configured to be in contact with the two heat-insulating members; and a heat-receiving portion including a heat-receiving surface configured to be in contact with outside air outside of the pipes, and configured to transfer heat, which is received from the outside air on the heat-receiving surface, to the contact portion.

### CROSS-REFERENCE TO RELATED APPLICATION

This application is based upon and claims the benefit of priority from Japanese Patent Application No. 2020-077574, filed on Apr. 24, 2020, the entire contents of which are incorporated herein by reference.

### TECHNICAL FIELD

The present disclosure relates to a piping system and a processing apparatus.

### BACKGROUND

In a processing apparatus that uses plasma to perform a predetermined process on a workpiece such as a semiconductor wafer, the temperature of the workpiece is controlled to a predetermined temperature. Since the workpiece is heated by plasma, it is important to cool the workpiece in order to maintain the temperature of the workpiece during a process using plasma at a predetermined temperature. For example, by circulating a cooling medium having a temperature lower than room temperature inside a stage on which the workpiece is placed, the workpiece is cooled via the stage.

### PRIOR ART DOCUMENT

### Patent Document

Patent Document 1: Japanese Laid-Open Patent Publication No. 2016-207840

### SUMMARY

According to an embodiment of the present disclosure, there is provided a piping system including: pipes, each of which is covered with a heat-insulating member and through which a cooling medium flows; and a heat transfer member arranged between two heat-insulating members of two of the pipes adjacent to each other, wherein the heat transfer member includes: a contact portion configured to be in contact with the two heat-insulating members; and a heat-receiving portion including a heat-receiving surface configured to be in contact with outside air outside of the pipes, and configured to transfer heat, which is received from the outside air on the heat-receiving surface, to the contact portion.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating an exemplary processing apparatus according to a first embodiment of the present disclosure.

FIG. 2 is a view schematically showing an exemplary temperature distribution at respective positions in the vicinity of adjacent pipes when the pipes are disposed so as to be spaced apart from each other.

FIG. 3 is a view schematically showing an exemplary temperature distribution at respective positions in the vicinity of adjacent pipes when the pipes are disposed close to each other.

FIG. 4 is a cross-sectional view illustrating exemplary pipes and an exemplary heat transfer member according to a first embodiment.

FIG. 5 is a view schematically showing an exemplary temperature distribution at respective positions in the vicinity of pipes when a heat transfer member is disposed between two heat-insulating members of adjacent pipes.

FIG. 6 is a view illustrating an example in which the outer circumferences of both of two heat-insulating members are partially covered with a heat-receiving portion.

FIG. 7 is a view illustrating an example in which the outer circumferences of both of two heat-insulating members are partially covered with a heat-receiving portion.

FIG. 8 is a view illustrating an example in which the outer circumference of one of two heat-insulating members is partially covered with a heat-receiving portion.

FIG. 9 is a view illustrating an exemplary heat-receiving portion extending in a plate shape.

FIG. 10 is a view illustrating an example in which fins are formed on a heat-receiving surface of a heat-receiving portion.

FIG. 11 is a view illustrating an example in which a surface roughening or a dot processing is performed on a heat-receiving surface of a heat-receiving portion.

FIG. 12 is a cross-sectional view illustrating exemplary pipes and an exemplary heat transfer member according to a second embodiment.

FIG. 13 is a view illustrating an example in which a contact portion and a heat-receiving portion are disposed, with air layers interposed between the contact portion and the heat-receiving portion and the outer circumferential surfaces of two heat-insulating members.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of a piping system and a processing apparatus disclosed herein will be described in detail with reference to the drawings. In each of the drawings, the same or corresponding parts will be denoted by the same reference numerals. The processing apparatus disclosed herein is not limited by the embodiments.

When the temperature of a workpiece on a stage is controlled by a cooling medium, pipes are used to allow the cooling medium to flow between the stage and a temperature controller (e.g., a chiller) that controls the temperature of the cooling medium. Each of the pipes is covered with a heat-insulating member in order to prevent the occurrence of dew condensation. In the processing apparatus, in the case in which pipes, each of which is covered with a heat-insulating member, are used, when the heat-insulating members of adjacent pipes are in contact with each other, heat from the outside air is taken up by the cooling medium without being transferred at a contact portion between the heat-insulating members. As a result, dew condensation may occur in the vicinity of the contact portion between the heat-insulating members. In the processing apparatus, when dew condensation occurs in the vicinity of the contact portion between the heat-insulating members, there is a risk that electronic parts or the like around the pipes will be damaged by the moisture generated by the dew condensation.

Therefore, it is desired to suppress the occurrence of dew condensation caused by the contact between heat-insulating members.

### First Embodiment

### [Configuration of Processing Apparatus 1]

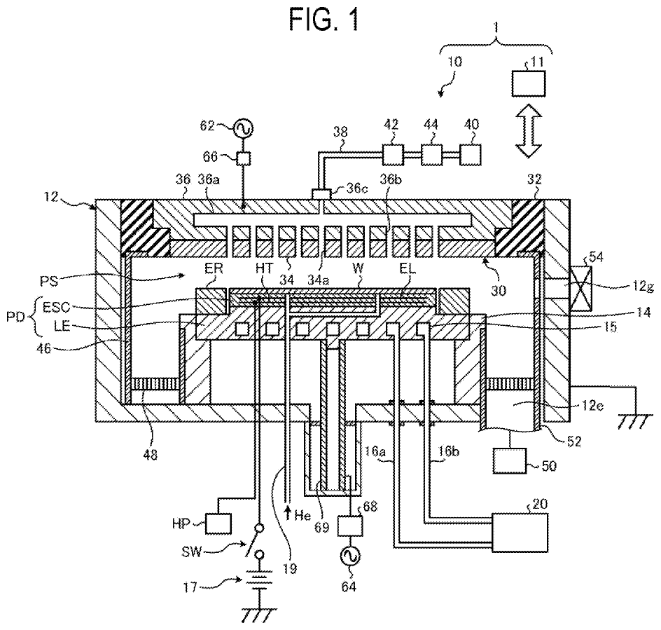

FIG. 1 is a schematic cross-sectional view illustrating an exemplary processing apparatus 1 in a first embodiment of the present disclosure. In the present embodiment, the processing apparatus 1 is, for example, a plasma etching apparatus including parallel flat plate electrodes. The processing apparatus 1 includes an apparatus body 10 and a controller 11. The apparatus body 10 includes a processing container 12 made of a material such as aluminum, and has, for example, a substantially cylindrical shape. The inner wall surface of the processing container 12 is anodized. The processing container 12 is grounded for safety.

On the bottom of the processing container 12, a substantially cylindrical support 14 made of an insulating material, such as quartz, is provided. The support 14 extends in the processing container 12 in the vertical direction (e.g., toward the upper electrode 30) from the bottom of the processing container 12.

A stage PD is provided in the processing container 12. The stage PD is supported by the support 14. The stage PD holds and supports a wafer W, which is a workpiece, on a top surface of the stage PD. The stage PD includes an electrostatic chuck ESC and a lower electrode LE. The lower electrode LE is made of a metal material such as aluminum, and has a substantially disk-like shape. The electrostatic chuck ESC is arranged on the lower electrode LE.

The electrostatic chuck ESC has a structure in which an electrode EL, which is a conductive film, is disposed between a pair of insulating layers or between a pair of insulating sheets. A DC power source 17 is electrically connected to the electrode EL via a switch SW. The electrostatic chuck ESC attracts the wafer W to the top surface of the electrostatic chuck ESC using an electrostatic force such as a Coulomb force generated by a DC voltage supplied from the DC power source 17. This makes it possible for the electrostatic chuck ESC to hold and support the wafer W.

A heat transfer gas such as He gas is supplied to the electrostatic chuck ESC through a pipe 19. The heat transfer gas supplied through the pipe 19 is supplied to a space between the electrostatic chuck ESC and the wafer W. By adjusting the pressure of the heat transfer gas supplied to the space between the electrostatic chuck ESC and the wafer W, it is possible to adjust the thermal conductivity between the electrostatic chuck ESC and the wafer W.

A heater HT, which is a heating element, is installed inside the electrostatic chuck ESC. A heater power source HP is connected to the heater HT. By supplying electric power from the heater power source HP to the heater HT, it is possible to heat the wafer W on the electrostatic chuck ESC via the electrostatic chuck ESC. The temperature of the wafer W placed on the electrostatic chuck ESC is adjusted by the lower electrode LE and the heater HT. The heater HT may be arranged between the electrostatic chuck ESC and the lower electrode LE.

An edge ring ER is arranged around the electrostatic chuck ESC so as to surround the edge of the wafer W and the electrostatic chuck ESC. The edge ring ER may be called a focus ring. The edge ring ER is capable of improving the in-plane uniformity of processing on the wafer W. The edge ring ER is made of a material appropriately selected depending on the material of a film to be etched, such as quartz.

Inside the lower electrode LE, a flow path 15 through which the cooling medium flows is formed. As the cooling medium, for example, brine or the like is used. A chiller 20 is connected to the flow path 15 via a pipe 16a and a pipe 16b. The chiller 20 circulates and supplies the cooling medium, the temperature of which is controlled to a predetermined temperature, to the flow path 15 inside the lower electrode LE via the pipe 16a and the pipe 16b. That is, the cooling medium, the temperature of which is controlled by the chiller 20, is supplied to the flow path 15 inside the lower electrode LE via the pipe 16a. The cooling medium, which has flowed through the flow path 15, is returned to the chiller 20 via the pipe 16b. As a result, the temperature of the wafer W placed on the lower electrode LE is controlled to a predetermined temperature. The lower electrode LE is an example of a heat exchanger configured to perform heat exchange between the cooling medium flowing therein and a workpiece. The chiller 20 is an example of a supplier.

Each of the pipes 16a and 16b is covered with a heat-insulating member. By covering each of the pipes 16a and 16b with the heat-insulating member, heat exchange is performed between the outside air of the pipes 16a and 16b and the surface of the heat-insulating member, and the surface of the heat-insulating member is maintained at a temperature higher than a dew point temperature. As a result, the occurrence of dew condensation on the surface of the heat-insulating member is suppressed.

A power-feeding pipe 69 is electrically connected to the bottom surface of the lower electrode LE to feed radio frequency power to the lower electrode LE. The power-feeding pipe 69 is made of metal. Although not illustrated in FIG. 1, lifter pins configured to deliver a wafer W on the electrostatic chuck ESC, a driving mechanism of the same, and the like are disposed in a space between the lower electrode LE and the bottom of the processing container 12.

A first radio frequency power source 64 is electrically connected to the power-feeding pipe 69 via a matcher 68. The first radio frequency power source 64 is a power source that generates radio frequency power for drawing ions into a wafer W, that is, radio frequency bias power, for example, a radio frequency bias having a frequency of 400 kHz to 40.68 MHz, for example, a frequency of 13.56 MHz. The matcher 68 is a circuit for matching the output impedance of the first radio frequency power source 64 with the input impedance on the load (the lower electrode LE) side. The radio frequency bias power generated by the first radio frequency power source 64 is supplied to the lower electrode LE via the matcher 68 and the power-feeding pipe 69.

An upper electrode 30 is installed above the stage PD and at a position facing the stage PD. The lower electrode LE and the upper electrode 30 are arranged substantially parallel to each other. Plasma is generated in the space between the upper electrode 30 and the lower electrode LE, and plasma processing such as etching is performed using the generated plasma on the wafer W held on the top surface of the electrostatic chuck ESC. The space between the upper electrode 30 and the lower electrode LE is a processing space PS.

The upper electrode 30 is supported in the upper portion of the processing container 12 via an insulative shielding member 32 made of, for example, quartz. The upper electrode 30 includes an electrode plate 34 and an electrode support 36. The lower surface of the electrode plate 34 faces the processing space PS. Gas ejection ports 34a are formed in the electrode plate 34. The electrode plate 34 is made of, for example, a material containing silicon.

The electrode support 36 is made of a conductive material such as aluminum, and detachably supports the electrode plate 34 from above. The electrode support 36 may have a water-cooling structure (not illustrated). A diffusion chamber 36a is formed inside the electrode support 36. From the diffusion chamber 36a, gas flow ports 36b communicating with the gas ejection ports 34a in the electrode plate 34 extend downward (toward the stage PD). The electrode support 36 is provided with a gas inlet 36c configured to guide a processing gas to the diffusion chamber 36a, and a pipe 38 is connected to the gas inlet 36c.

A gas source group 40 is connected to the supply pipe 38 via a valve group 42 and a flow rate controller group 44. The gas source group 40 includes gas sources. The valve group 42 includes valves, and the flow rate controller group 44 includes flow controllers such as mass flow controllers. Each gas source in the gas source group 40 is connected to the pipe 38 via a corresponding valve in the valve group 42 and a corresponding flow controller in the flow rate controller group 44.

This makes it possible for the apparatus body 10 to supply a processing gas from one or more gas sources selected in the gas source group 40 to the diffusion chamber 36a in the electrode support 36 at an individually adjusted flow rate. The processing gas supplied to the diffusion chamber 36a diffuses in the diffusion chamber 36a, and is supplied in the form of a shower into the processing space PS through respective gas flow ports 36b and gas ejection ports 34a.

A second radio frequency power source 62 is electrically connected to the electrode support 36 via a matcher 66. The second radio frequency power source 62 is a power source that generates radio frequency power for plasma generation, and generates radio frequency power having a frequency of 27 MHz to 100 MHz, for example, 60 MHz. The matcher 66 is a circuit for matching the output impedance of the second radio frequency power source 62 with the input impedance on the load (the upper electrode 30) side. The radio frequency power generated by the second radio frequency power source 62 is supplied to the upper electrode 30 via the matcher 66. The second radio frequency power source 62 may be connected to the lower electrode LE via the matcher 66.

A deposition shield 46, which is made of for example, aluminum having a surface coated with Y₂O₃ or quartz, is detachably installed on the inner wall surface of the processing container 12 and the outer surface of the support 14. The deposition shield 46 is capable of preventing etching byproducts (deposition) from adhering to the processing container 12 and the support 14.

Between the outer wall of the support 14 and the inner wall of the processing container 12 and near the bottom portion of the processing container 12 (near the portion in which the support 14 is installed), an exhaust plate 48, which is made of aluminum having a surface coated with Y₂O₃, quartz, or the like, is provided. An exhaust port 12e is formed below the exhaust plate 48. An exhaust apparatus 50 is connected to the exhaust port 12e via an exhaust pipe 52.

The exhaust apparatus 50 has a vacuum pump such as a turbo molecular pump, and is capable of reducing the pressure inside the processing container 12 to achieve a desired degree of vacuum. An opening 12g is formed in the side wall of the processing container 12 so as to load/unload the wafer W therethrough, and the opening 12g is configured to be capable of being opened and closed by a gate valve 54.

The controller 11 has a memory, a processor, and an input/output interface. The memory stores a program executed by the processor and a recipe including conditions for respective processes. The processor executes the program read from the memory, and controls each part of the apparatus body 10 via the input/output interface based on the recipe stored in the memory, thereby performing a predetermined process such as etching on a wafer W.

In the processing apparatus 1 using therein pipes through which a cooling medium passes, heat-insulating members of adjacent pipes may be in contact with each other. When the heat-insulating members of adjacent pipes are in contact with each other, heat from the outside air is taken up by the cooling medium without being transferred to a contact portion between the heat-insulating members. As a result, condensation may occur in the vicinity of the contact portion between the heat-insulating members. For example, in the processing apparatus 1, when the pipes 16a and 16b are adjacent to each other and the heat-insulating members of the pipes 16a and 16b are in contact with each other, dew condensation may occur in the vicinity of the contact portion between the heat-insulating members of the pipes 16a and 16b.

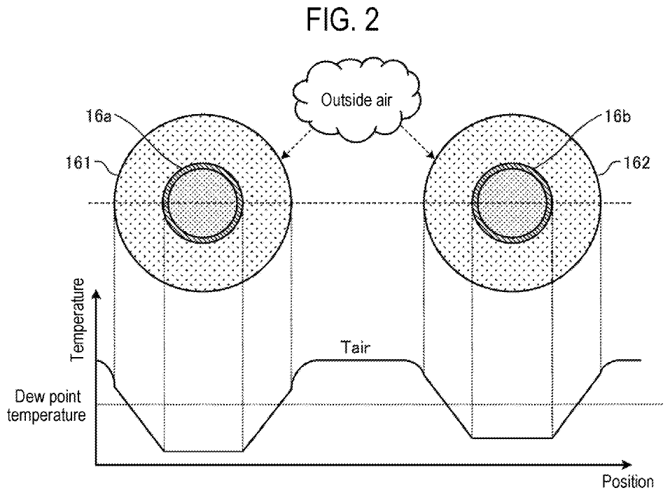

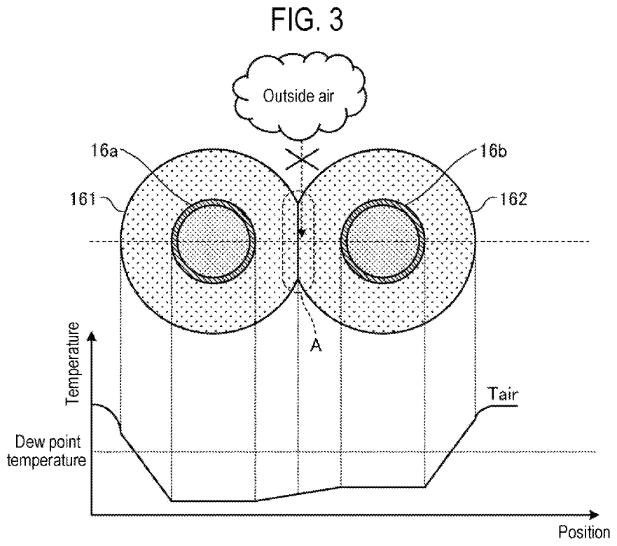

Here, with reference to FIGS. 2 and 3, the mechanism of dew condensation generation in the vicinity of the contact portion between the heat-insulating members of adjacent pipes will be described. FIG. 2 is a view schematically showing an exemplary temperature distribution at respective positions in the vicinity of adjacent pipes 16a and 16b when the pipes 16a and 16b are disposed so as to be spaced apart from each other. FIG. 2 illustrates each of the cross sections of adjacent pipes 16a and 16b. As illustrated in FIG. 2, the pipe 16a is covered with a heat-insulating member 161, and the pipe 16b is covered with a heat-insulating member 162. A cooling medium supplied from the chiller 20 to the flow path 15 inside the lower electrode LE flows through the inside of the pipe 16a, and the cooling medium returned to the chiller 20 from the flow path 15 inside the lower electrode LE flows through the inside of the pipe 16b. In the state in which the pipes 16a and 16b are spaced apart from each other, entire circumferences (entire outer circumferential surfaces) of the heat-insulating members 161 and 162 of the pipes 16a and 16b are in contact with the outside air of the pipes 16a and 16b. Therefore, the entire circumferences (entire outer circumferential surfaces) of the heat-insulating members 161 and 162 of the pipes 16a and 16b receive heat from the outside air and are maintained at a temperature near the temperature Tair of the outside air. As a result, the temperature of the surfaces of the heat-insulating members 161 and 162 of the pipes 16a and 16b becomes higher than the dew point temperature, and dew condensation does not occur on the surfaces of the heat-insulating members 161 and 162 of the pipes 16a and 16b.

For comparison, the case in which the adjacent pipes 16a and 16b are disposed close to each other will be described. FIG. 3 is a view schematically showing an exemplary temperature distribution at respective positions in the vicinity of adjacent pipes 16a and 16b when the pipes 16a and 16b are disposed close to each other. In the processing apparatus 1, when the pipes 16a and 16b are close to each other, the heat-insulating member 161, which covers the pipe 16a, and the heat-insulating member 162, which covers the pipe 16b, may be in contact with each other. In FIG. 3, the contact portion between the heat-insulating members 161 and 162 is illustrated as the contact portion A. Heat from the outside air is taken up by the cooling medium without being transferred to the contact portion A, and thus the temperature in the vicinity of the contact portion A is lowered. In addition, in the processing apparatus 1, when the temperature in the vicinity of the contact portion A drops below the dew point temperature, dew condensation occurs at the contact portion A.

Therefore, in the processing apparatus 1, a heat transfer member is disposed between the two heat-insulating members 161 and 162 of two of the pipes 16a and 16b adjacent to each other.

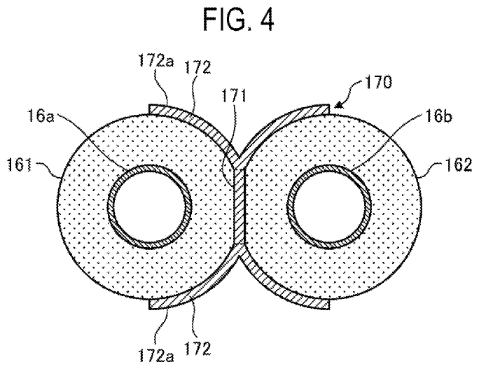

FIG. 4 is a cross-sectional sectional view illustrating exemplary pipes 16a and 16b and an exemplary heat transfer member 170 according to the first embodiment. In the processing apparatus 1, the heat transfer member 170 is disposed between the heat-insulating member 161, which covers the pipe 16a, and the heat-insulating member 162, which covers the pipe 16b. The heat transfer member 170 is formed of a material having a thermal conductivity higher than that of the heat-insulating members 161 and 162, and has a contact portion 171 and heat-receiving portions 172. Examples of the material having a thermal conductivity higher than that of the heat-insulating members 161 and 162 include a metal such as aluminum (Al). The contact portion 171 and the heat-receiving portions 172 are integrally formed, but in FIG. 4, the boundary lines between the contact portion 171 and the heat-receiving portions 172 are indicated by broken lines for convenience of description.

The contact portion 171 is in contact with the two heat-insulating members 161 and 162. That is, the contact portion 171 is in contact with the two heat-insulating members 161 and 162 in the state of being interposed between the two heat-insulating members 161 and 162.

The heat-receiving portions 172 are portions on which heat-receiving surfaces 172a, which are in contact with the outside air outside of the pipes 16a and 16b, are formed. The heat-receiving portions 172 transfer the heat, which is received from the outside air on the heat-receiving surfaces 172a, to the contact portion 171.

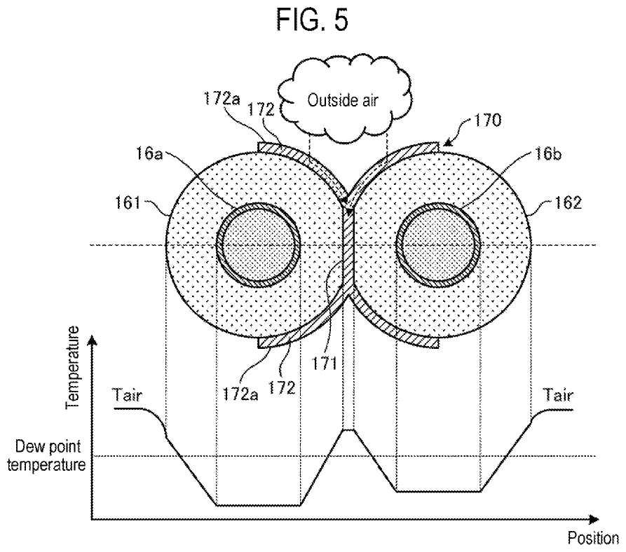

Here, a change in temperature distribution at respective positions in the vicinity of adjacent pipes 16a and 16b due to the arrangement of a heat transfer member 170 between two heat-insulating members 161 and 162 of the pipes 16a and 16b is described with reference to FIG. 5. FIG. 5 is a view schematically showing an exemplary temperature distribution at respective positions in the vicinity of adjacent pipes 16a and 16b when a heat transfer member 170 is arranged between two heat-insulating members 161 and 162 of the pipes 16a and 16b. FIG. 5 illustrates each of the cross sections of the adjacent pipes 16a and 16b. As illustrated in FIG. 5, the pipe 16a is covered with a heat-insulating member 161, and the pipe 16b is covered with a heat-insulating member 162. A cooling medium supplied from the chiller 20 to the inner flow path 15 of the lower electrode LE flows through the inside of the pipe 16a, and the cooling medium returned to the chiller 20 from the flow path 15 inside the lower electrode LE flows through the inside of the pipe 16b. A heat transfer member 170 is arranged between the two heat-insulating members 161 and 162. The heat transfer member 170 has a contact portion 171 and heat-receiving portions 172. As illustrated in FIG. 5, the heat-receiving surfaces 172a formed on the heat-receiving portions 172 are in contact with the outside air outside of the pipes 16a and 16b, and receive heat from the outside air. The heat received on the heat-receiving surfaces 172a is transferred to the contact portion 171. In FIG. 5, the path of heat transferred from the outside air of the pipes 16a and 16b to the contact portion 171 is indicated by the broken line arrows. When the heat received on the heat-receiving surfaces 172a is transferred to the contact portion 171, the temperature of the contact portion 171 is maintained at a temperature near the temperature Tair of the outside air. This makes it possible to maintain the temperature of a contact portion in which the contact portion 171 and the two heat-insulating members 161 and 162 are in contact with one another at a temperature higher than the dew point temperature. That is, the contact portion 171 and the heat-receiving portions 172 (that is, the heat transfer member 170) are capable of suppressing a temperature drop of the contact portion in which the contact portion 171 and the two heat-insulating members 161 and 162 are in contact with one another. As a result, it is possible to suppress the formation of dew condensation caused by the contact between the heat-insulating members 161 and 162.

A description will be made referring back to FIG. 4. The heat-receiving portions 172 are arranged so as to partially cover the outer circumferences (outer circumferential surfaces) of both of the heat-insulating members 161 and 162. For example, when the cross-sectional shape of each of the two heat-insulating members 161 and 162 is cylindrical, the heat-receiving portions 172 are arranged such that heat-receiving portions 172 cover a range corresponding to approximately half of the circumference for each of the outer circumferences of the two heat-insulating members 161 and 162 from both end portions of the contact portion 171.

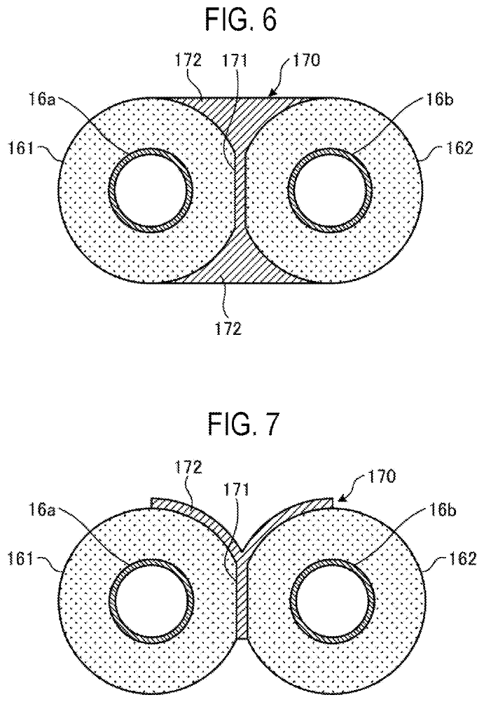

The heat-receiving portions 172 may be arranged as illustrated in FIGS. 6 and 7, as long as the outer circumferences (outer circumferential surfaces) of the two heat-insulating members 161 and 162 are partially covered. For example, as illustrated in FIG. 6, the heat-receiving portions 172 may be arranged so as to fill all of the spaces interposed between the outer circumferences of both of the two heat-insulating members 161 and 162. In addition, as illustrated in FIG. 7, the heat-receiving portions 172 may be arranged to cover a range corresponding to approximately ¼ of the circumference for each of the outer circumferences of the two heat-insulating members 161 and 162 from one end portion of the contact portion 171. FIGS. 6 and 7 are views each illustrating an example in which both outer circumferences of the two heat-insulating members 161 and 162 are partially covered with the heat-receiving portions 172.

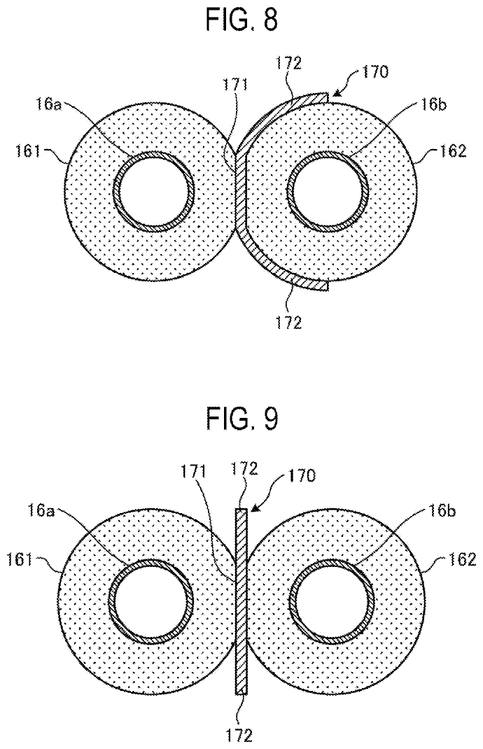

The heat-receiving portions 172 may be arranged so as to partially cover the outer circumference (outer circumferential surface) of one of the two heat-insulating members 161 and 162. FIG. 8 is a view illustrating an example in which the outer circumference (outer circumferential surface) of one of the two heat-insulating members 161 and 162 is partially covered with the heat-receiving portions 172. The heat-receiving portions 172 illustrated in FIG. 8 are arranged so as to cover a range corresponding to approximately half of the circumference from both end portions of the contact portion 171 for the outer circumference of the heat-insulating member 162.

In addition, the heat-receiving portions 172 may be configured so as not to be in contact with the outer circumferences of the two heat-insulating members 161 and 162. That is, as illustrated in FIG. 9, the heat-receiving portions 172 may be arranged so as to extend in a plate shape from the end portions of the contact portion 171 toward the outside air outside of the pipes 16a and 16b. FIG. 9 is a view illustrating an exemplary heat-receiving portion 172 extending in a plate shape.

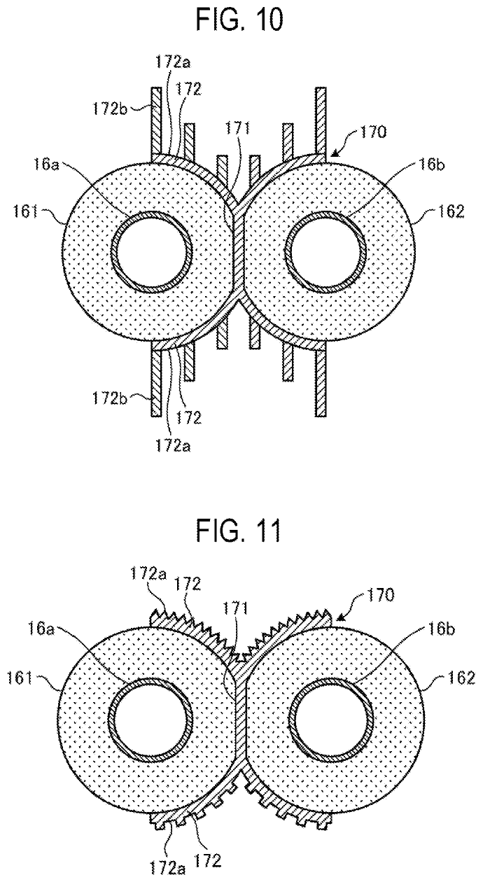

In addition, the heat-receiving portions 172 may be configured to include portions for increasing the surface area of the heat-receiving surfaces 172a in order to promote reception of heat from the outside air outside of the pipes 16a and 16b. That is, as illustrated in FIG. 10, the heat-receiving portions 172 may have fins 172b formed on the heat-receiving surfaces 172a. FIG. 10 is a view illustrating an example in which the fins 172b are formed on the heat-receiving surfaces 172a of the heat-receiving portions 172. As shown in FIG. 11, a surface roughening or a dot processing may be performed on the heat-receiving surfaces 172a of the heat-receiving portions 172. FIG. 11 illustrates the state in which the surface roughening is performed on the heat-receiving surfaces 172a of the upper heat-receiving portions 172 and the dot processing is performed on the heat-receiving surfaces 172a of the lower heat-receiving portions 172. FIG. 11 is a view illustrating an example in which the surface roughening or the dot processing is performed on the heat-receiving surfaces 172a of the heat-receiving portions 172.

As described above, the processing apparatus 1 according to the first embodiment includes the heat transfer member 170 arranged between the two heat-insulating members 161 and 162 of the adjacent pipes 16a and 16b. The heat transfer member 170 includes the contact portion 171, which is in contact with the two heat-insulating members 161 and 162, and the heat-receiving portions 172, which include the heat-receiving surfaces 172a being in contact with the outside air outside of the pipes 16a and 16b and transfer the heat received on the heat-receiving surface 172a to the contact portion 171. This makes it possible for the processing apparatus 1 to suppress the occurrence of dew condensation due to the contact between the heat-insulating members 161 and 162.

### Second Embodiment

Next, a second embodiment will be described. The second embodiment relates to a variation of the arrangement aspect of the heat-receiving portions 172 in the first embodiment.

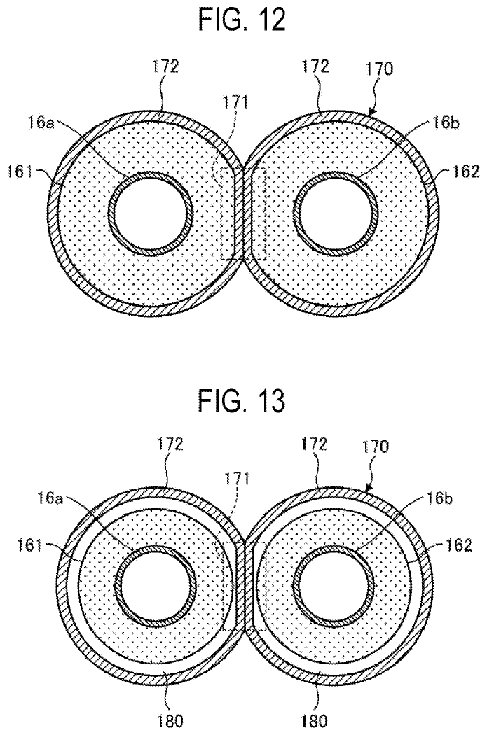

FIG. 12 is a cross-sectional sectional view illustrating exemplary pipes 16a and 16b and an exemplary heat transfer member 170 according to the second embodiment. In the processing apparatus 1, the heat transfer member 170 is disposed between the heat-insulating member 161, which covers the pipe 16a, and the heat-insulating member 162, which covers the pipe 16b. The heat transfer member 170 is arranged so as to surround the entire circumferences (entire outer circumferential surfaces) of both of the two heat-insulating members 161 and 162.

The heat transfer member 170 has a contact portion 171 and heat-receiving portions 172, which are integrally formed. The contact portion 171 is in contact with the two heat-insulating members 161 and 162. The heat-receiving portions 172 are arranged so as to cover the entire circumferences (entire outer circumferential surfaces) of both of the two heat-insulating members 161 and 162 in an annular shape together with the contact portion 171. The contact portion 171 is formed to include a first portion that is in contact with one of the two heat-insulating members 161 and 162 and a second portion that is in contact with the other one of the two heat-insulating members 161 and 162, while the first and second portions are separated from each other. That is, the contact portion 171 and the heat-receiving portions 172 form two covers that cover the entire circumferences of both of the two heat-insulating members 161 and 162, respectively.

The contact portion 171 and the heat-receiving portions 172 (that is, the heat transfer member 170) are capable of suppressing a temperature drop of the contact portion in which the contact portion 171 and the two heat-insulating members 161 and 162 are in contact with one another, similarly to the heat transfer member 170 of the first embodiment. In addition, since the contact portion 171 and the heat-receiving portions 172 form the two covers that cover the entire circumferences of both of the two heat-insulating members 161 and 162, respectively, each of the covers prevents contact between the two heat-insulating members 161 and 162 even when the heat-insulating members 161 and 162 are twisted in the circumferential direction.

The heat transfer member 170 (that is, the contact portion 171 and the heat-receiving portions 172) may be arranged such that gaps are interposed between the heat transfer member 170 and the outer circumferential surfaces of the two heat-insulating members 161 and 162. That is, the heat transfer member 170 may be arranged such that air layers formed by the gaps are interposed between the heat transfer member 170 and the outer circumferential surfaces of the two heat-insulating members 161 and 162. FIG. 13 is a view illustrating an example in which the heat transfer member 170 is arranged with air layers interposed between the heat transfer member 170 and the outer circumferential surfaces of the two heat-insulating members 161 and 162. The heat transfer member 170 illustrated in FIG. 13 is arranged such that air layers 180 formed by the gaps are interposed between the heat transfer member 170 and the outer circumferential surfaces of the two heat-insulating members 161 and 162. By arranging the air layer 180 to be interposed between the heat transfer member 170 and the outer circumferential surfaces of the two heat-insulating members 161 and 162, the heat insulation performance of the pipes 16a and 16b can be improved.

As described above, in the processing apparatus 1 according to the second embodiment, the heat-receiving portions 172 are arranged so as to cover the entire circumferences (entire outer circumferential surfaces) of both of the two heat-insulating members 161 and 162 in an annular shape together with the contact portion 171. This makes it possible for the processing apparatus 1 to suppress the occurrence of dew condensation due to the contact between the heat-insulating members 161 and 162 even when the two heat-insulating members 161 and 162 are twisted.

In addition, in the processing apparatus 1 according to the second embodiment, the heat-receiving portions 172 may be arranged so as to cover the entire circumferences (entire outer circumferential surfaces) of both of the two heat-insulating members 161 and 162 along the longitudinal direction of the pipes 16a and 16b in a tubular shape together with the contact portion 171. This makes it possible for the processing apparatus 1 to suppress the occurrence of dew condensation due to the contact between the heat-insulating members 161 and 162 even if the two heat-insulating members 161 and 162 are twisted at an arbitrary position in the longitudinal direction of the pipes 16a and 16b.

It shall be understood that the embodiments disclosed herein are illustrative and are not restrictive in all aspects. The above embodiments may be omitted, replaced, or modified in various forms without departing from the scope and spirit of the appended claims.

For example, in the second embodiment described above, the case in which the heat-receiving portions 172 are arranged such that the heat-receiving portions 172 cover the entire circumferences (entire outer circumferential surfaces) of both of the two heat-insulating members 161 and 162 in an annular shape together with the contact portion 171 has been described as an example. However, the technique disclosed herein is not limited thereto. For example, a heat-receiving portion 172 is arranged so as to cover the entire circumference of one of the two heat-insulating members 161 and 162 in an annular shape together with the contact portion 171. In this case, the contact portion 171 is in contact with one of the two heat-insulating members 161 and 162, and thus is not separated.

In each of the above-described embodiments, the case in which the cross-sectional shape of each of the two heat-insulating members 161 and 162 is a cylindrical shape has been described as an example, but the technique disclosed herein is not limited thereto. For example, the cross-sectional shape of each of the two heat-insulating members 161 and 162 may be a tubular shape, rather than the cylindrical shape. Examples of the tubular shape, rather than the cylindrical shape, include a square tubular shape and a triangular tubular shape. When the cross-sectional shape of each of the two heat-insulating members 161 and 162 is a tubular shape, rather than the cylindrical shape, the heat-receiving portions 172 may be arranged so as to appropriately cover the range corresponding to the cross-sectional shape of each of the two heat-insulating members 161 and 162.

In each of the embodiments described above, capacitively coupled plasma (CCP) is used as an example of a plasma source, but the technique disclosed herein is not limited thereto. As the plasma source, for example, inductively coupled plasma (ICP), microwave-excited surface wave plasma (SWP), electron cyclotron resonance plasma (ECP), or helicon wave-excited plasma (HWP) may be used.

In each of the above-described embodiments, a plasma etching apparatus is described as an example of the processing apparatus 1, but the technique disclosed herein is not limited thereto. In addition to an etching apparatus, the technique disclosed herein is applicable to any of a film forming apparatus, a modification apparatus, a cleaning apparatus, and the like, as long as pipes, each of which is covered with a heat-insulating member and through which a cooling medium flows, are used therein.

According to the present disclosure, it is possible to suppress occurrence of dew condensation caused by contact between heat-insulating members.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A piping system comprising:
pipes, each of which is covered with a heat-insulating member and through which a cooling medium flows; and
a heat transfer member arranged between two heat-insulating members of two of the pipes adjacent to each other,
wherein the heat transfer member includes:
a contact portion configured to be in contact with the two heat-insulating members; and
a heat-receiving portion including a heat-receiving surface configured to be in contact with outside air outside of the pipes, and configured to transfer heat, which is received from the outside air on the heat-receiving surface, to the contact portion.

2. The piping system of claim 1, wherein the heat transfer member is made of a material having a thermal conductivity higher than a thermal conductivity of a material of the heat-insulating member.

3. The piping system of claim 2, wherein the contact portion and the heat-receiving portion are integrally formed.

4. The piping system of claim 3, wherein the heat-receiving portion is arranged so as to partially cover an outer circumference of one or both of the two heat-insulating members.

5. The piping system of claim 4, wherein the heat-receiving portion includes fins on the heat-receiving surface.

6. The piping system of claim 1, wherein the contact portion and the heat-receiving portion are integrally formed.

7. The piping system of claim 1, wherein the heat-receiving portion is arranged so as to partially cover an outer circumference of one or both of the two heat-insulating members.

8. The piping system of claim 1, wherein the heat-receiving portion is arranged so as to cover an entire circumference of one or both of the two heat-insulating members in an annular shape together with the contact portion.

9. The piping system of claim 8, wherein the heat-receiving portion is arranged so as to cover the entire circumference of one or both of the two heat-insulating members along a longitudinal direction of the pipes in a tubular shape together with the contact portion.

10. The piping system of claim 9, wherein the heat-receiving portion and the contact portion are arranged such that a gap is interposed between the heat-receiving portion and the contact portion and an outer circumferential surface of the heat-insulating member.

11. The piping system of claim 8, wherein the contact portion is formed to include a first portion that is in contact with one of the two heat-insulating members and a second portion that is in contact with the other one of the two heat-insulating members, while the first and second portions are separated from each other.

12. The piping system of claim 1, wherein the heat-receiving portion is arranged so as to extend in a plate shape from an end of the contact portion toward the outside air outside of the pipes.

13. The piping system of claim 1, wherein the heat-receiving portion includes fins on the heat-receiving surface.

14. The piping system of claim 1, wherein a surface roughening or a dot processing is performed on the heat-receiving surface of the heat-receiving portion.

15. A processing apparatus comprising:
a processing container in which a workpiece is processed;
a heat exchanger installed in the processing container and configured to perform heat exchange between a cooling medium flowing through the heat exchanger and the workpiece;
a supplier configured to supply the cooling medium to the heat exchanger;
pipes connected to the heat exchanger and the supplier, through which the cooling medium flows, each of the pipes being covered with a heat-insulating member; and
a heat transfer member arranged between two heat-insulating members of two of the pipes adjacent to each other,
wherein the heat transfer member includes:
a contact portion configured to be in contact with the two heat-insulating members; and
a heat-receiving portion including a heat-receiving surface configured to be in contact with outside air outside of the pipes, and configured to transfer heat, which is received from the outside air on the heat-receiving surface, to the contact portion.
